(19) United States
(12) Patent Application Publication
(10) Pub. No.: US 2020/0170136 A1
(43) Pub. Date: May 28, 2020

(54) MOVING ASSISTANCE STRUCTURE

(71) Applicant: NANNING FUGUI PRECISION INDUSTRIAL CO., LTD., Nanning (CN)

(72) Inventor: YING-JUI HUANG, New Taipei (TW)

(21) Appl. No.: 16/199,172

(22) Filed: Nov. 24, 2018

(51) Int. Cl. H05K 7/14; B25B 9/00

(52) U.S. Cl. CPC H05K 7/1415; B65G 7/12; B25B 9/00

(57) ABSTRACT

A moving assistance structure coupled to an end of a component for assisting in pushing the component into a cabinet or pulling the component out of the cabinet includes a mounting member and a driving member. The mounting member is mounted to the component. The driving member is rotationally coupled to the mounting member and includes a first abutting portion and a second abutting portion. The first abutting portion abuts the cabinet when the driving member is rotated along a first direction to push the component into the cabinet. The second abutting portion abuts the cabinet when the driving member is rotated along a second direction opposite to the first direction to pull the component out of the cabinet.

### FIELD

The subject matter herein generally relates to a moving assistance structure adapted for assisting in moving a component in and out of a cabinet.

### BACKGROUND

Generally, components of cabinets, such as power supply systems or server racks, require moving structures to move the components in and out of the cabinets. The moving structures generally do not exert force outside of an external force of moving the moving structures, and the moving structures may be too large to be handled conveniently.

Therefore, there is room for improvement within the art.

### BRIEF DESCRIPTION OF THE DRAWINGS

Implementations of the present disclosure will now be described, by way of embodiments only, with reference to the attached figures.

FIG. 1 is an assembled, isometric view of an embodiment of a moving assistance structure.

FIG. 2 is an exploded, isometric view of the moving assistance structure according to FIG. 1.

FIG. 3 is an isometric view of a mounting member of the moving assistance structure according to FIG. 1.

FIG. 4 is an isometric view of the moving assistance structure according to FIG. 1 showing a handle of the moving assistance structure in an extended position.

FIG. 5 is a cross-sectional view of the moving assistance structure mounted to a component received in a cabinet.

FIG. 6 is a cross-sectional view of FIG. 5 showing the moving assistance structure being rotated along a first direction to pull the component out of the cabinet.

FIG. 7 is a cross-sectional view of FIG. 5 showing the moving assistance structure being rotated along a second direction to push the component into the cabinet.

FIG. 8 is a cross-sectional view of FIG. 5 showing a driving member of the moving assistance structure defining an angle with the cabinet to pull the component out of the cabinet.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

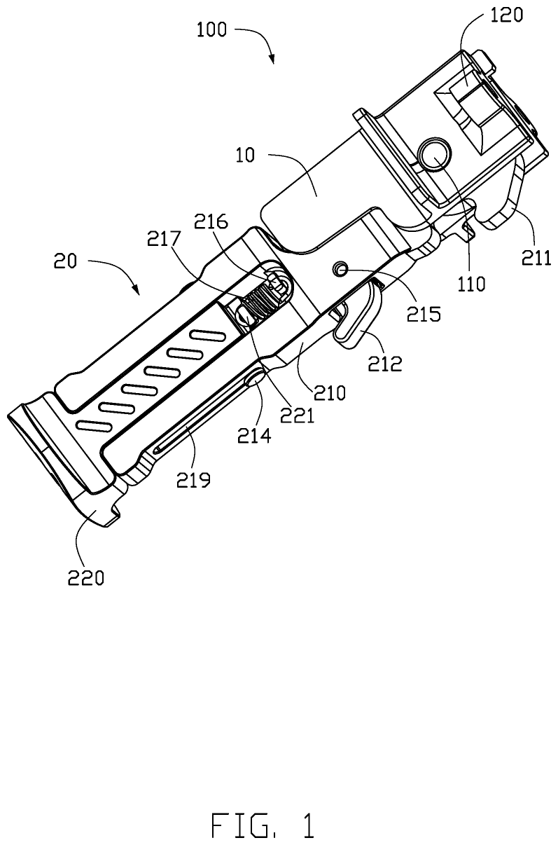

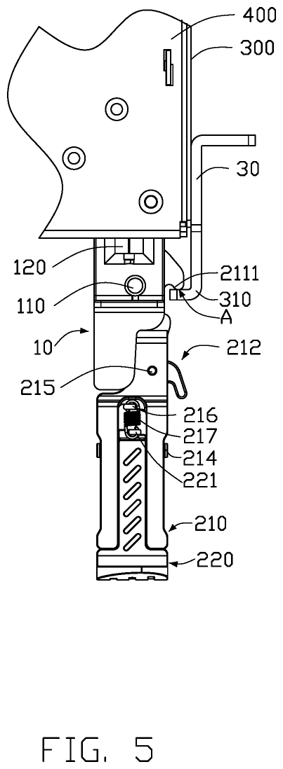

FIG. 1 illustrates an embodiment of a moving assistance structure 100 including a mounting member 10 and a driving member 20. The mounting member 10 is mounted to a component 400 (illustrated in FIGS. 5-8). The driving member 20 is rotationally coupled to the mounting member 10. The component 400 may be a power supply system or other device to be stored in a cabinet 300 (illustrated in FIGS. 5-8). The moving assistance structure 100 assists in pushing the component 400 into the cabinet 300 or pulling the component 400 out of the cabinet 300.

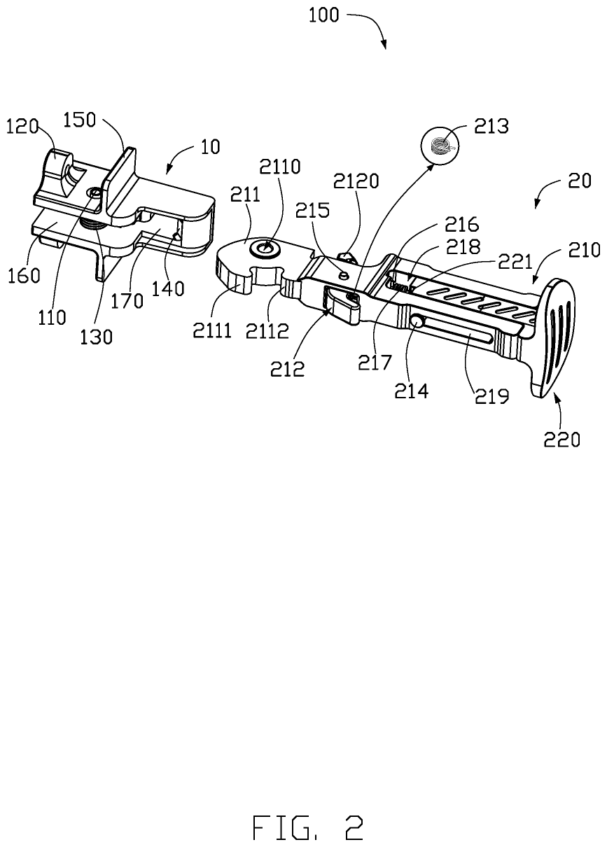

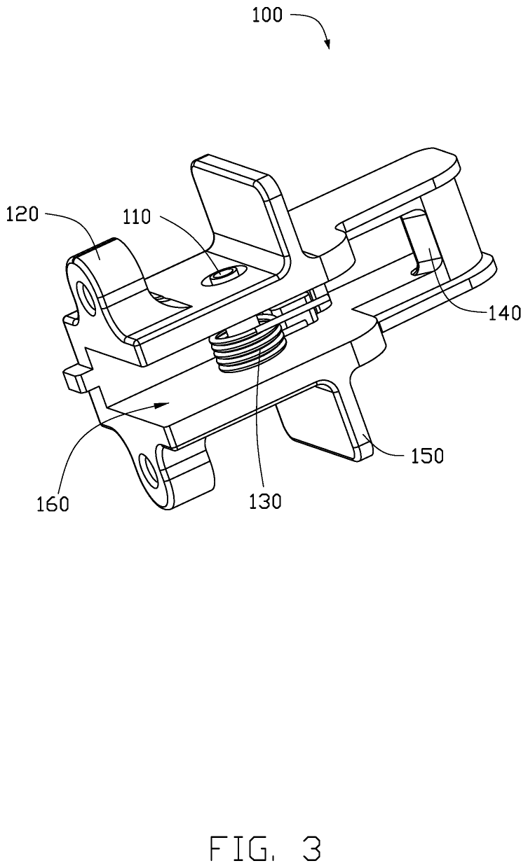

As illustrated in FIGS. 2 and 3, the mounting member 10 defines a groove 160. The mounting member 10 includes a first stud 110. A first resilient member 130 is sleeved over the first stud 110 and received within the groove 160. In one embodiment, the first resilient member 130 is a spring, such as a torsional spring. The mounting member 10 includes a buckle 140 within the groove 160. An outer surface of the mounting member 10 forms a mounting step 120. The mounting step 120 is adapted to mounted to the component 400 to mount the mounting member 10 to the component 400.

The driving member 20 includes a driving frame 210 and a handle 220. The driving frame 210 is rotationally coupled to the mounting member 10. The handle 220 is slidably coupled to the driving frame 210.

The driving frame 210 includes a fixing portion 211, a latching button 212, a second resilient member 213, a fastening member 214, and a third resilient member 217. In one embodiment, the third resilient member 217 is a spring, such as a compression spring. The driving frame 210 defines a through hole (not labeled), a through slot 218, and a chute 219. The fixing portion 211 defines a columnar hole 2110 and forms a first abutting portion 2111 and a second abutting portion 2112. The first resilient member 130 restores a position of the first abutting portion 2111 and the second abutting portion 2112. The latching button 212 includes a hook portion 2120.

The latching button 212 is received within the through hole. A second stud 215 passes through the driving frame 210 and the latching button 212 to rotationally couple the latching button 212 to the driving frame 210. The second resilient member 213 is sleeved over the second stud 215 to restore a position of the latching button 212. The second resilient member 213 is a spring, such as a torsional spring. The handle 220 is slidably mounted within the chute 219 by the fastening member 214. The third resilient member 217 is coupled between the driving frame 210 and the handle 220. The third resilient member 217 is a spring, such as a compression spring.

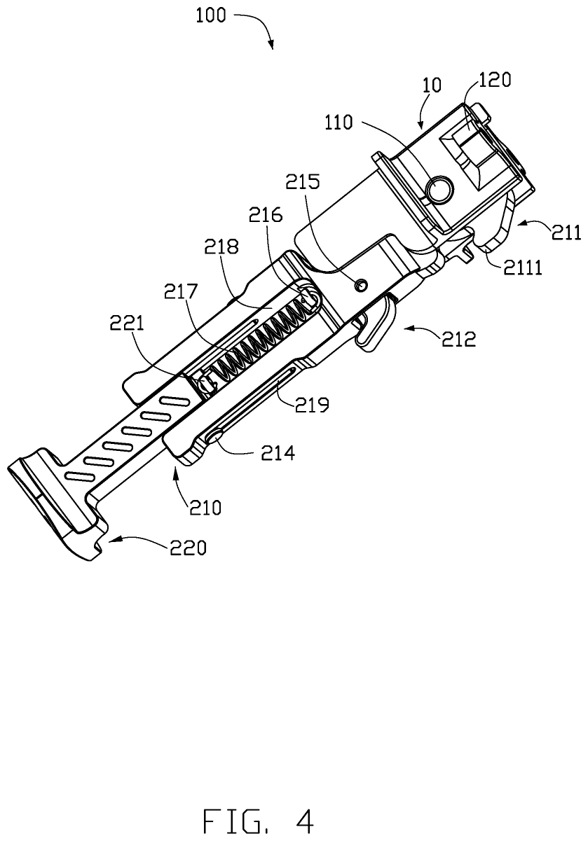

As illustrated in FIGS. 2 and 4, the fixing portion 211 rotationally mounts the driving frame 210 to the mounting member 10. The latching button 212 latches the driving frame 210 to the buckle 140 or releases the driving frame 210 from the buckle 140.

As illustrated in FIG. 5, the cabinet 300 includes a sidewall 30. The sidewall 30 includes a bent portion 310.

When the moving assistance structure 100 is in the position as illustrated in FIG. 5, the third resilient member 217 is compressed, and the handle 220 is received within the driving frame 210. The first abutting portion 2111 abuts the bent portion 310 at a point A, and the hook portion 2120 of the latching button 212 latches the buckle 140 of the mounting member 10. The mounting member 10, the driving frame 210, and the handle 220 are aligned collinearly, and the component 400 is received within the cabinet 300.

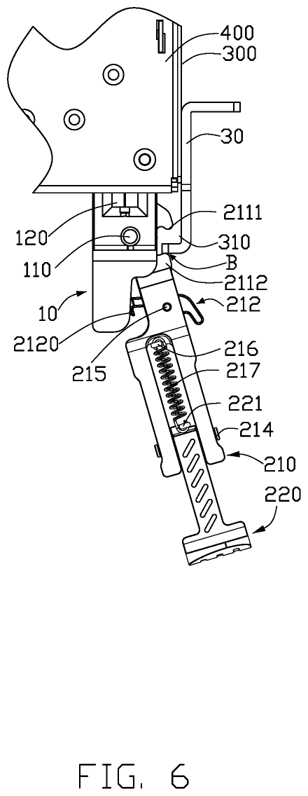

As illustrated in FIG. 6, to pull the component 400 out from the cabinet 300, the handle 220 is pulled to extend the handle 220 along the chute 219 to extend the third resilient member 217. The latching button 212 is pressed to cause the hook portion 2120 to remove from the buckle 140. Then, the handle 220 is pulled to rotate the driving frame 210 about the first stud 110 along a first direction to cause the second abutting member 2112 to abut the bent portion 310 at a point B. The driving member 20 is rotated continuously to cause the mounting member 10 to be pulled out the component 400. When the first abutting portion 2111 passes the bent portion 310, the component 400 can be pulled out of the cabinet 300.

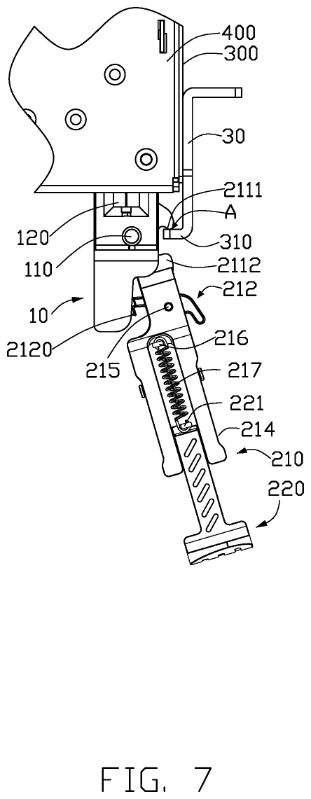

As illustrated in FIG. 7, to push the component 400 into the cabinet 300, the handle 220 is pulled to extend the handle 220 along the chute 219 to extend the third resilient member 217, and the handle 220 is pulled to rotate the driving frame 210 about the first stud 110 along a second direction opposite to the first direction to cause the first abutting portion 2111 to abut the bent portion 310 at the point A. The latching button 212 is pressed, and the driving member 20 is rotated until the component 400 is received within the cabinet 300. Then the latching button 212 is released to cause the hook portion 2120 of the latching button 212 to latch the buckle 140 of the mounting member 10 to complete a process of pushing the component 400 within the cabinet 300.

After the component 400 is received within the cabinet 300, the handle 220 may be pressed to cause the handle 220 to be partially received within the driving frame 210.

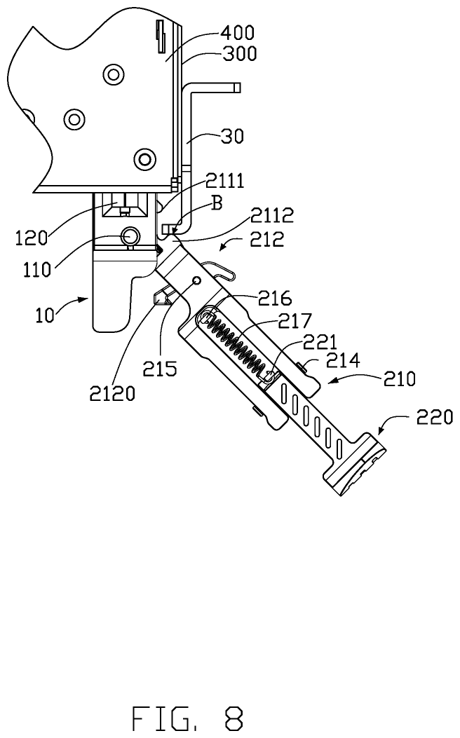

As illustrated in FIG. 8, when the driving member 20 is rotated until the driving member 20 is at a predetermined angle relative to the cabinet 300, the component 400 can be pulled out of the cabinet 300. At the predetermined angle, the first abutting portion 2111 is moved past the bent portion 310. In one embodiment, the predetermined angle is 45 degrees. When the component 400 is received within the cabinet 300, the fixing portion 211 abuts a side of the bent portion 310.

The driving member 20 is substantially perpendicular to the cabinet 300. The driving member 20 is rotated along an outer side of the cabinet 300. Thus, the driving member 20 is not blocked by the cabinet 300 from rotating. When the handle 220 is not in use, the handle 220 is received within the through slot 218 so that a door of the cabinet 300 is not blocked from closing. The moving assistance structure 100 is arranged adjacent the sidewall 30 so that the moving assistance structure 100 does not occupy much space within the cabinet 300.

In other embodiments, the component 400 may be mounted to two moving assistance structures 100, such that each of the moving assistance structure 100 is arranged adjacent a corresponding side of the component 400.

The handle 220 is substantially T-shaped. Opposite ends of the handle 220 are curved, and the handle 220 does not slip within the chute 219 to increase operation of the handle 220. The through slot 218 is substantially U-shaped, but may be other shapes in other embodiments. The driving frame 210 includes a first connecting buckle 216, and the handle 220 includes a second connecting buckle 221. The third resilient member 217 is coupled between the first connecting buckle 216 and the second connecting buckle 221. There are two mounting steps 120 oppositely arranged on the mounting member 10.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A moving assistance structure coupled to an end of a component adapted for assisting in pushing the component into a cabinet or pulling the component out of the cabinet, the moving assistance structure comprising:
a mounting member mounted to the component;
a driving member rotationally coupled to the mounting member and comprising a first abutting portion and a second abutting portion; wherein:
the first abutting portion abuts the cabinet when the driving member is rotated along a first direction to push the component into the cabinet; and
the second abutting portion abuts the cabinet when the driving member is rotated along a second direction opposite to the first direction to pull the component out of the cabinet.

2. The moving assistance structure of claim 1, wherein:
the driving member comprises a driving frame and a handle;
the driving frame is rotationally coupled to the mounting member; and
the handle is slidably coupled to the driving frame.

3. The moving assistance structure of claim 2, wherein:
one end of the driving frame comprises a fixing portion;
the first abutting portion and the second abutting portion are formed on the fixing portion;
the mounting member comprises a first resilient member restoring a position of the first abutting portion and the second abutting portion.

4. The moving assistance structure of claim 3, wherein:
when the fixing portion and the cabinet define a predetermined angle, the first abutting portion and the second abutting portion do not abut the cabinet, and the fixing portion is adapted for pulling the component out of the cabinet.

5. The moving assistance structure of claim 1, wherein:
the mounting member defines a groove and a buckle protruding from within the groove;
the driving member comprises a latching button;
the latching button comprises a hook portion; and
the latching button drives the driving member to latch with the mounting member by the hook portion.

6. The moving assistance structure of claim 5, wherein:
the driving member comprises a second resilient member received within the latching button;
a position of the latching button is restored by the second resilient portion.

7. The moving assistance structure of claim 2, wherein:
the driving frame defines a through slot and a chute;
the driving frame comprises a third resilient member coupled between the driving frame and the handle;
the handle is movably received within the chute through the third resilient member;
the handle is received within the chute or extended out of the chute.

8. The moving assistance structure of claim 1, wherein:
the driving member is coupled to the mounting member;
the driving member abuts the cabinet and rotates on an outer side of the cabinet.

9. A cabinet comprising a moving assistance structure abutting a sidewall of the cabinet adapted for pushing a component within the cabinet or pulling the component out of the cabinet, the moving assistance structure coupled to an end of the component and comprising:
a mounting member mounted to the component;
a driving member rotationally coupled to the mounting member and comprising a first abutting portion and a second abutting portion; wherein:
the first abutting portion abuts the cabinet when the driving member is rotated along a first direction to push the component into the cabinet; and
the second abutting portion abuts the cabinet when the driving member is rotated along a second direction opposite to the first direction to pull the component out of the cabinet.

10. The cabinet of claim 9, wherein:
the driving member comprises a driving frame and a handle;
the driving frame is rotationally coupled to the mounting member; and
the handle is slidably coupled to the driving frame.

11. The cabinet of claim 10, wherein:
one end of the driving frame comprises a fixing portion;
the first abutting portion and the second abutting portion are formed on the fixing portion;
the mounting member comprises a first resilient member restoring a position of the first abutting portion and the second abutting portion.

12. The cabinet of claim 11, wherein:
when the fixing portion and the cabinet define a predetermined angle, the first abutting portion and the second abutting portion do not abut the cabinet, and the fixing portion is adapted for pulling the component out of the cabinet.

13. The cabinet of claim 9, wherein:
the mounting member defines a groove and a buckle protruding from within the groove;
the driving member comprises a latching button;
the latching button comprises a hook portion;
the latching button drives the driving member to latch with the mounting member by the hook portion.

14. The cabinet of claim 13, wherein:
the driving member comprises a second resilient member received within the latching button;
a position of the latching button is restored by the second resilient portion.

15. The cabinet of claim 10, wherein:
the driving frame defines a through slot and a chute;
the driving frame comprises a third resilient member coupled between the driving frame and the handle;
the handle is movably received within the chute through the third resilient member;
the handle is received within the chute or extended out of the chute.

16. The cabinet of claim 9, wherein:
the driving member is coupled to the mounting member;
the driving member abuts the cabinet and rotates on an outer side of the cabinet.
